(19) United States
(12) Patent Application Publication
(10) Pub. No.: US 2004/0016402 A1
(43) Pub. Date: Jan. 29, 2004

(54) Methods and apparatus for monitoring plasma parameters in plasma doping systems

(76) Inventors: Steven R. Walther, Andover, MA (US); Ziwei Fang, Beverly, MA (US); Bon-Woong Koo, Andover, MA (US); Susan B. Felch, Los Altos Hills, CA (US)

Correspondence Address: Wolf, Greenfield & Sacks, P.C., 600 Atlantic Avenue, Boston, MA, 02210-2211, US

(21) Appl. No.: 10/205,961

(22) Filed: Jul. 26, 2002

(51) Int. Cl. C23C 16/00

(52) U.S. Cl. 118/723 E

(57) ABSTRACT

Methods and apparatus are provided for monitoring plasma parameters in plasma doping systems. A plasma doping system includes a plasma doping chamber, a platen located in the plasma doping chamber for supporting a workpiece, an anode spaced from the platen in the plasma doping chamber, a process gas source coupled to the plasma doping chamber, a pulse source for applying pulses between the platen and the anode, and a plasma monitor. A plasma containing ions of the process gas is produced in a plasma discharge region between the anode and the platen. The pulses accelerate ions from the plasma into the workpiece. The plasma monitor may include a sensing device which senses a spatial distribution of a plasma parameter, such as plasma density, that is indicative of dose distribution of ions implanted into the workpiece.

### FIELD OF THE INVENTION

This invention relates to plasma doping systems used for ion implantation of workpieces and, more particularly, to methods and apparatus for monitoring plasma parameters in plasma doping systems.

### BACKGROUND OF THE INVENTION

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of the wafer. The energetic ions in the beam penetrate into the bulk of the semiconductor material and are embedded into the crystalline lattice of the semiconductor material to form a region of desired conductivity.

A well-known trend in the semiconductor industry is toward smaller, higher speed devices. In particular, both the lateral dimensions and the depths of features in semiconductor devices are decreasing. State of the art semiconductor devices require junction depths less than 1,000 Angstroms and may eventually require junction depths on the order of 200 Angstroms or less. The implanted depth of the dopant material is determined, at least in part, by the energy of the ions implanted into the semiconductor wafer. Beamline ion implanters are typically designed for efficient operation at relatively high implant energies and may not function efficiently at the low energies required for shallow junction implantation.

Plasma doping systems have been studied for forming shallow junctions in semiconductor wafers. In a plasma doping system, a semiconductor wafer is placed on a conductive platen, which functions as a cathode and is located in a plasma doping chamber. An ionizable process gas containing the desired dopant material is introduced into the chamber, and a voltage pulse is applied between the platen and an anode or the chamber walls, causing formation of a plasma having a plasma sheath in the vicinity of the wafer. The applied pulse causes ions in the plasma to cross the plasma sheath and to be implanted into the wafer. The depth of implantation is related to the voltage applied between the wafer and anode. Very low implant energies can be achieved. Plasma doping systems are described, for example, in U.S. Pat. No. 5,354,381, issued Oct. 11, 1994 to Sheng; U.S. Pat. No. 6,020,592, issued Feb. 1, 2000 to Liebert et al.; and U.S. Pat. No. 6,182,604, issued Feb. 6, 2001 to Goeckner et al.

In the plasma doping system described above, the applied voltage pulse generates a plasma and accelerates positive ions from the plasma toward the wafer. In other types of plasma systems, known as plasma immersion systems, a continuous plasma is produced, for example, by inductively coupled RF power from an antenna located internal or external to the plasma doping chamber. The antenna is connected to an RF power supply. At intervals, voltage pulses are applied between the platen and the anode, causing positive ions in the plasma to be accelerated toward the wafer.

Exacting requirements are placed on semiconductor fabrication processes involving ion implantation, with respect to the cumulative ion dose implanted into the wafer and spatial dose uniformity across the wafer surface. The implanted dose determines the electrical activity of the implanted region, whereas dose uniformity is required to ensure that all devices on the semiconductor wafer have operating characteristics within specified limits.

In a plasma doping system, the plasma which generates the ions is located at the surface of the wafer. Spatial dose uniformity depends on the uniformity of the plasma and on the electric fields in the vicinity of the wafer. However, the plasma may have spatial nonuniformities and may vary with time. Such plasma nonuniformities are likely to produce dose nonuniformity in the wafers being processed. A plasma doping system which utilizes a separately biased concentric structure surrounding the platen to improve dose uniformity is disclosed in U.S. Pat. No. 5,711,812, issued Jan. 27, 1998 to Chapek et al. Despite the improvement produced by this approach, dose uniformity remains an issue in plasma doping systems.

Accordingly, there is a need for methods and apparatus for monitoring the performance of plasma doping systems.

### SUMMARY OF THE INVENTION

According to a first aspect of the invention, plasma doping apparatus is provided. The plasma doping apparatus comprises a plasma doping chamber, a platen located in the plasma doping chamber for supporting a workpiece, an anode spaced from the platen in the plasma doping chamber, a process gas source coupled to the plasma doping chamber, a pulse source for applying pulses between the platen and the anode, and a plasma monitor. A plasma containing ions of the process gas is produced in a plasma discharge region between the anode and the platen. The pulses applied between the platen and the anode accelerate ions from the plasma into the workpiece. The plasma monitor comprises a sensing device which senses a spatial distribution of a plasma parameter. The sensed spatial distribution of the plasma parameter may be indicative of dose distribution of ions implanted into the workpiece.

In some embodiments, the sensing device comprises an array of sensors disposed within the plasma doping chamber in spaced relation to the workpiece. The sensors may be mounted in or near the anode. The sensors may comprise optical sensors or electrical sensors. The sensor array may comprise a linear array or a two-dimensional array. In a plasma doping chamber having a cylindrical geometry, a circular array or a radial array of sensors may be utilized.

In some embodiments, the sensing device comprises one or more image sensors for acquiring images of the plasma in the plasma discharge region.

In some embodiments, the sensing device comprises a movable sensor disposed in the plasma doping chamber in spaced relation to the workpiece and an actuator for moving the sensor with respect to the plasma.

The plasma monitor may further comprise processing circuitry connected to the sensors. The measurements acquired by the sensors are provided to the processing circuitry, which computes an estimate of the dose distribution of ions implanted into the workpiece.

According to another aspect of the invention, a method for plasma doping is provided. The method comprises the steps of supporting a workpiece on a platen in a plasma doping chamber, generating a plasma in the plasma doping chamber and accelerating ions from the plasma into the workpiece, and sensing a spatial distribution of a plasma parameter. The spatial distribution of the plasma parameter may be indicative of dose distribution of ions implanted into the workpiece.

According to a further aspect of the invention, plasma doping apparatus is provided. The plasma doping apparatus comprises a plasma doping chamber, a platen located in the plasma doping chamber for supporting a workpiece, an anode spaced from the platen in the plasma doping chamber, a process gas source coupled to the plasma doping chamber, a pulse source for applying pulses between the platen and the anode, and a plasma monitor. A plasma containing ions of the process gas is produced in a plasma discharge region between the anode and the platen. The pulses applied between the platen and the anode accelerate ions from the plasma into the workpiece. The plasma monitor comprises an optical sensor for sensing optical emissions from the plasma over a selected wavelength range and processing circuitry connected to the optical sensor for processing the sensed optical emissions over the selected wavelength range.

According to another aspect of the invention, a method for plasma doping is provided. The method comprises the steps of supporting a workpiece on a platen in a plasma doping chamber, generating a plasma and accelerating ions from the plasma into the workpiece, sensing optical emissions from the plasma over a selected wavelength range, and processing the sensed optical emissions over the selected wavelength range to provide a measurement value that is representative of a condition of the plasma.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a plasma doping system;

FIG. 2 is a partial schematic, cross-sectional view of a plasma doping system, illustrating a first embodiment of a plasma monitor;

FIG. 3 is a bottom view of the anode, illustrating a second embodiment of a plasma monitor;

FIG. 4 is a bottom view of the anode, illustrating a third embodiment of a plasma monitor;

FIG. 5 is a bottom view of the anode, illustrating a fourth embodiment of a plasma monitor;

FIG. 6 is a bottom view of the anode, illustrating a fifth embodiment a plasma monitor;

FIG. 7 is a bottom view of the anode, illustrating a sixth embodiment of a plasma monitor;

FIG. 8 is a partial schematic, cross-sectional view of a plasma doping system, illustrating a seventh embodiment of a plasma monitor;

FIG. 9 is an enlarged, partial cross-sectional view of the anode shown in FIG. 8;

FIG. 10 is a top view of the anode shown in FIG. 8;

FIG. 11 is a schematic block diagram of processing electronics for processing the outputs of the plasma monitor shown in FIG. 8;

FIG. 12 is a graph of an example of a sensor signal as a function of time;

FIG. 13 is a partial cross-sectional view of a plasma doping system, illustrating an eighth embodiment of a plasma monitor;

FIG. 14 is a partial cross-sectional view of a plasma doping system, illustrating a ninth embodiment of a plasma monitor;

FIG. 15 is a partial cross-sectional view of a plasma doping system, illustrating a tenth embodiment of a plasma monitor;

FIG. 16 is a partial cross-sectional view of a plasma doping system, illustrating an eleventh embodiment of a plasma monitor;

FIG. 17A is a graph of relative intensity of sensed optical emissions as a function of radial position in a plasma doping system;

FIG. 17B is a graph of relative Therma-Wave values as a function of radial position in the plasma doping system;

FIG. 17C is a graph of relative ion current as a function of radial position in the plasma doping system;

FIG. 18 is a graph of normalized optical signal as a function of wafer current for different wavelength ranges; and

FIG. 19 is a graph of optical signal as a function of wafer current for different operating pressures.

### DETAILED DESCRIPTION

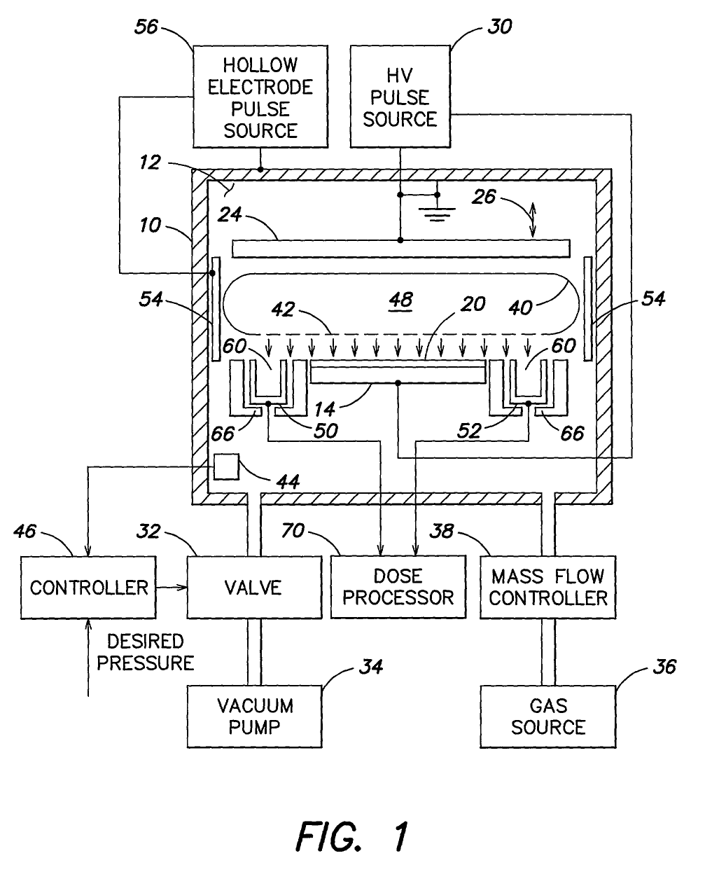

An example of a plasma doping system suitable for implementation of the present invention is shown schematically in FIG. 1. A plasma doping chamber 10 defines an enclosed volume 12. A platen 14 positioned within chamber 10 provides a surface for holding a workpiece, such as a semiconductor wafer 20. The wafer 20 may, for example, be clamped at its periphery to a flat surface of platen 14. In one embodiment, the-platen has an electrically conductive surface for supporting wafer 20. In another embodiment, the platen includes conductive pins (not shown) for connection to wafer 20. Wafer 20 and platen 14 function as a cathode in the plasma doping system.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In another configuration, platen 14 is connected to ground and anode 24 is pulsed.

In the configuration where anode 24 is connected to ground, wafer 20 (via platen 14) is connected to a high voltage pulse source 30. The pulse source 30 typically provides pulses in a range of about 100 to 5000 volts in amplitude, about 1 to 50 microseconds in duration and a pulse repetition rate of about 100 Hz to 2 kHz. It will be understood that these pulse parameter values are given by way of example only and that other values may be utilized within the scope of the invention.

The enclosed volume 12 of chamber 10 is coupled through a controllable valve 32 to a vacuum pump 34. A process gas source 36 is coupled through a mass flow controller 38 to chamber 10. A pressure sensor 44 located within chamber 10 provides a signal indicative of chamber pressure to a controller 46. The controller 46 compares the sensed chamber pressure with a desired pressure input and provides a control signal to valve 32. The control signal controls valve 32 so as to minimize the difference between the chamber pressure and the desired pressure. Vacuum pump 34, valve 32, pressure sensor 44 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Examples of ionizable gas include BF₃, N₂, Ar, PH₃, AsH₃ and B₂H₆. Mass flow controller 38 regulates the rate at which gas is supplied to chamber 10. The configuration shown in FIG. 1 provides a continuous flow of process gas at a constant gas flow rate and constant pressure. The pressure and gas flow rate are preferably regulated to provide repeatable results.

The plasma doping system may include a hollow cathode 54 connected to a hollow cathode pulse source 56. In one embodiment, the hollow cathode 54 comprises a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

One or more Faraday cups may be positioned adjacent to platen 14 for measuring the ion dose implanted into wafer 20. In the embodiment of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ions accelerated from plasma 40 toward platen 14. In another embodiment, an annular Faraday cup is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

As described in the aforementioned U.S. Pat. No. 5,711,812, the plasma doping system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

In operation, wafer 20 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to wafer 20, causing formation of a plasma 40 in a plasma discharge region 48 between wafer 20 and anode 24. As known in the art, plasma 40 contains positive ions of the ionizable gas from gas source 36. Plasma 40 includes a plasma sheath 42 in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, gas pressure and species and any variable position of the electrodes. For example, the cathode-to-anode spacing may be adjusted for different voltages.

Ion dose uniformity over the surface of wafer 20 depends on the uniformity of plasma 40 and on the electric fields in the vicinity of wafer 20. However, plasma 40 may have spatial nonuniformities and may vary with time. Accordingly, there is a need for techniques for monitoring the performance of plasma doping systems.

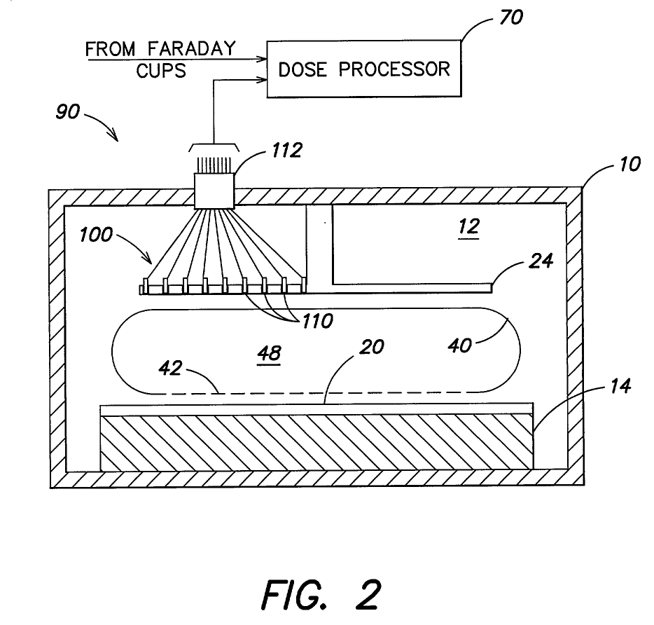

Embodiments of the invention are described with reference to FIGS. 2-19. Like elements in FIGS. 1-19 have the same reference numerals. The embodiments illustrated in FIGS. 2-19 may be utilized in a plasma doping system of the type shown in FIG. 1 and described above, or in any other plasma doping system.

According to an aspect of the invention, the plasma doping system is provided with a plasma monitor for monitoring the dose distribution of ions implanted into the wafer or other workpiece. The plasma monitor includes a sensing device, such as an array of sensors, for sensing the spatial distribution of a plasma parameter, and processing circuitry for processing the sensor signals to provide an indication of dose uniformity. The plasma monitor may be utilized in real time during an implant or may be utilized as a diagnostic tool.

A partial cross-sectional view of an embodiment of a plasma doping system is shown in FIG. 2. The plasma doping system includes a plasma monitor 90 according to a first embodiment of the invention. The plasma monitor 90 may include a sensing device 100 for sensing the spatial distribution of a parameter associated with plasma 40, and processing circuitry, which may be incorporated into dose processor 70, for processing the output signals of sensing device 100. The sensed plasma parameter is representative of the dose distribution of ions implanted into the workpiece. In some embodiments, sensing device 100 senses the spatial distribution of plasma density of plasma 40 in the plasma discharge region between anode 24 and platen 14.

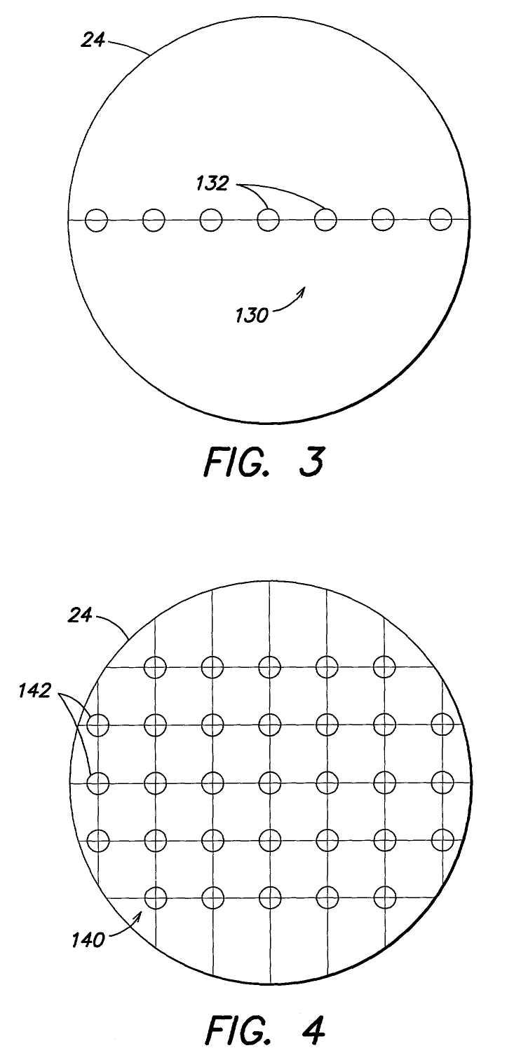

In the embodiment of FIG. 2, sensing device 100 includes an array of spaced-apart plasma sensors 110 mounted in anode 24. The plasma sensors 110 may be optical sensors or electrical sensors, for example. Each sensor 110 is directed toward platen 14 and senses a region of plasma 40. Sensors 110 may be electrically connected through a vacuum feedthrough 112 to dose processor 70 or other dose controller. In the embodiment of FIG. 2, sensors 110 are spaced apart along a radius of anode 24. Other embodiments of sensing device 100 are shown in FIGS. 3-7 and described below.

In the embodiment where sensors 110 are optical sensors, each optical sensor 110 views light emitted from a region of plasma 40. The acquired optical signal is indicative of the local plasma density, which can be correlated with the dose rate delivered to wafer 20 in the region viewed by the optical sensor. The array of sensors 110 provides information about the spatial variation of plasma intensity, which is useful as a diagnostic tool for making the implanted dose more uniform and for improving implant dose repeatability. The sensor array may also be used for real-time monitoring of the spatial variation of plasma intensity during plasma doping of a semiconductor wafer or other workpiece. The sensors 110 are preferably positioned in spaced relation to wafer 20 or other workpiece and are oriented to measure optical omission from the plasma in plasma discharge region 48. The multiple measurements by the array of sensors 110 are used to make a dose map that is used to characterize the uniformity of the implant.

As noted above, sensors 110 may be optical sensors or electrical sensors. In one embodiment, each sensor 110 is a photodiode or other photosensor mounted in anode 24. In another embodiment, each sensor 110 includes an optical probe, such as a lens, mounted in anode 24, a remotely-located photosensor and an optical fiber for carrying the sensed optical emission to the remotely-located photosensor. The lens may focus the sensed optical emission on the end of the optical fiber. The photosensor may be located outside the plasma doping chamber. In yet another embodiment, an image sensing device, such as a CCD image sensor, may be utilized. Where the sensing device 100 is sensing the spatial distribution of a plasma parameter, the number of sensors and the sensor configuration depend on the desired spatial resolution. Different sensor arrays may be utilized as described below. In the case of an image sensor, one or more sensors may be utilized to monitor the plasma. In some embodiments, the optical sensors monitor optical emissions from a selected wavelength range in the visible and near infrared portions of the spectrum. The sensed optical emissions may be averaged or integrated over the selected wavelength range. In another embodiment, the optical sensors monitor optical emissions from a narrow band, such as certain optical emissions from the gas molecules in the plasma doping chamber.

In further embodiments, sensors 110 may be electrical sensors which sense charged particles, typically electrons, in a region of the plasma adjacent to each sensor. The electrical sensor may be a conductive element that is electrically isolated from the anode 24.

Second through sixth embodiments of sensing devices in accordance with the invention are shown in FIGS. 3-7, respectively. Each of FIGS. 3-7 is a bottom view of anode 24 showing a sensing device configuration. In the embodiments of FIGS. 3-7, the plasma doping chamber has a cylindrical geometry and anode 24 is circular. However, the invention may be used for monitoring the spatial distribution of a plasma parameter in a chamber having any geometry.

The sensing device includes one or more sensors which may be mounted in anode 24 or in proximity thereto. For example, the sensors may be mounted in front of anode 24 in positions suitable for viewing plasma 40 or may be mounted behind anode 24 and may monitor plasma 40 through one or more openings in anode 24. The sensing device may utilize a single sensor, an image sensor, a fixed array of sensors, or one or more moving sensors.

Referring to FIG. 3, a linear array 130 of sensors 132 is shown. Sensors 132 may be spaced apart along a diameter of anode 24.

Referring to FIG. 4, a two-dimensional array 140 of sensors 142 is shown. In the embodiment of FIG. 4, sensors 142 are located on a two-dimensional grid having equally spaced rows and columns. The two-dimensional array 140 may cover an area sufficient to monitor plasma 40 (FIGS. 1 and 2), at least in the region of wafer 20.

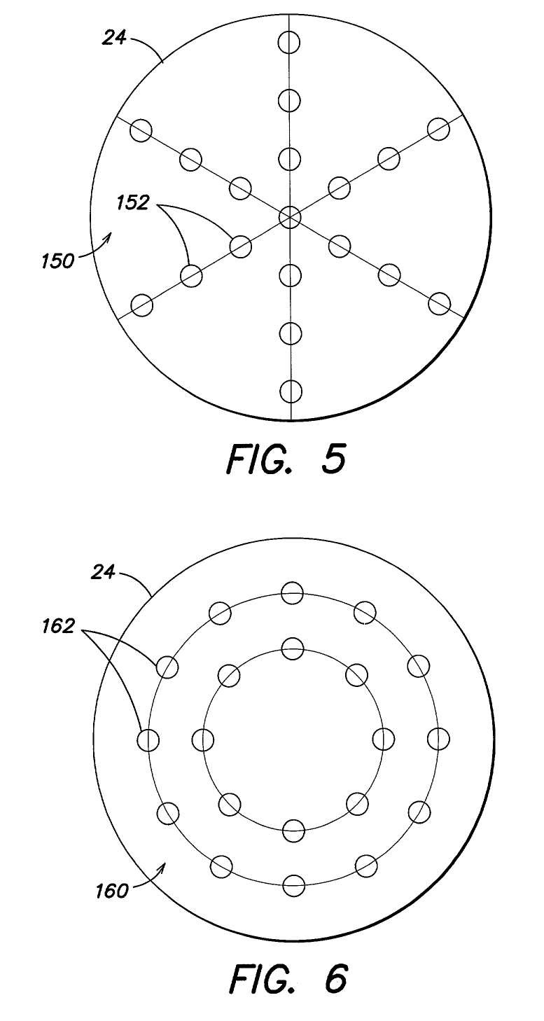

Referring to FIG. 5, a two-dimensional array 150 of sensors 152 is shown. In the embodiment of FIG. 5, the two-dimensional array 150 includes two or more linear arrays of sensors 152 aligned along diameters of anode 24 and azimuthally spaced to provide a desired monitoring resolution.

Referring to FIG. 6, a two-dimensional array 160 of sensors 162 is shown. The two-dimensional array 160 may include one or more circular arrays of sensors 162, with the circular arrays being concentric with anode 24.

The number of sensors, the spacing between sensors and the array configuration of the sensors depend on the sensor characteristics and on the desired monitoring resolution. The spacing between sensors in the array may be uniform or may vary. In general, an arbitrary spatial arrangement of sensors may be utilized. Sensor 170 may be an optical sensor or an electrical sensor.

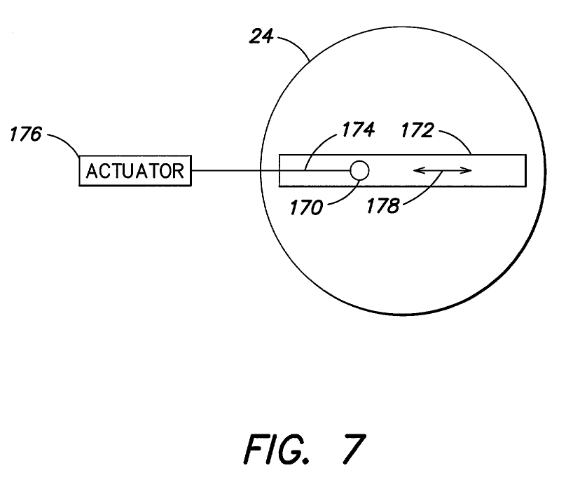

A configuration utilizing a moving sensor rather than a fixed sensor array is shown in FIG. 7. In the embodiment of FIG. 7, a sensor 170 is positioned in a slot 172 in anode 24. Sensor 170 is coupled by a drive shaft 174 to an actuator 176, such as a drive motor. Actuator 176 moves sensor 170 along slot 172 in a direction indicated by arrow 178. Sensor 170 may monitor plasma 40 continuously along its range of travel or at a series of discrete locations along its range of travel. In general, one or more movable actuators may be utilized. Sensor 170 may be an optical sensor or an electrical sensor. A moving sensor avoids the need for calibration between individual sensors in an array of sensors.

As discussed above, the sensing device may include one or more image sensors, such as CCD image sensors. The number and positions of the image sensors depend on the field of view of the image sensors and the desired monitoring coverage. For example, several spaced-apart image sensors may be utilized to monitor the plasma.

The outputs of the sensor or sensors may be supplied to dose processor 70 (FIG. 2), along with the outputs of Faraday cups 50 and 52. The outputs of the plasma sensors provide spatial information as to a plasma parameter, such as plasma density. The plasma parameter is preferably related to ion dose implanted into wafer 20. Therefore, the plasma spatial information is indicative of the dose distribution of the ions implanted into wafer 20. The Faraday cups 50 and 52 provide information as to ion dose implanted into wafer 20. From these measurements, dose processor 70 may determine the dose and dose uniformity in the implanted wafer.

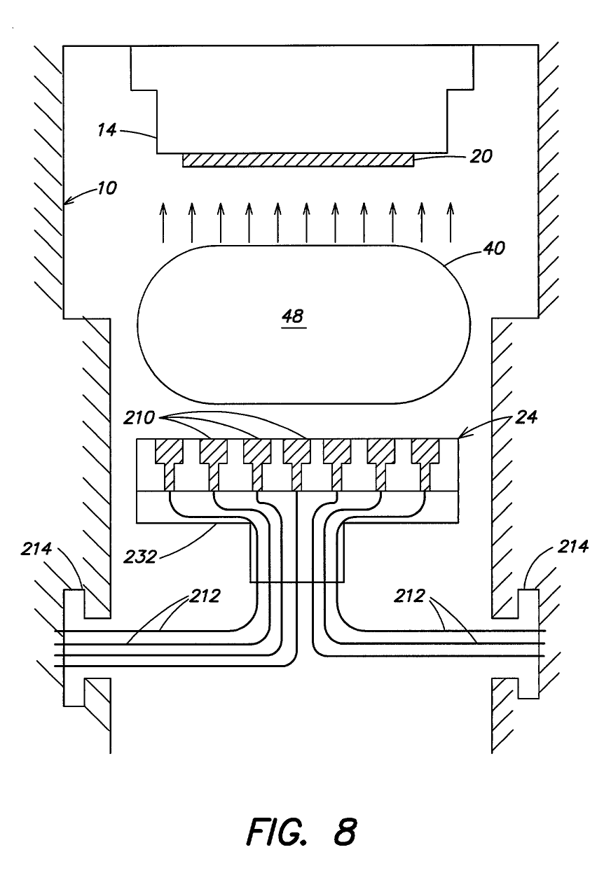

A seventh embodiment of a plasma monitor in accordance with the invention is described with reference to FIGS. 8-12. As shown in FIG. 8, the plasma doping system has an inverted geometry as compared to FIG. 1, with platen 14 and wafer 20 positioned above plasma 40, and anode 24 positioned below plasma 40.

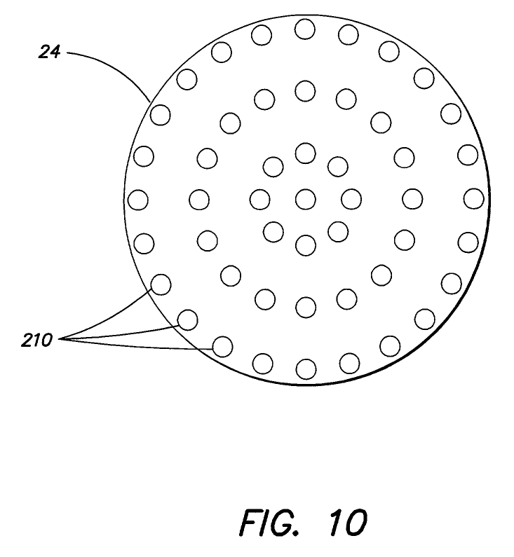

Electrical sensors 210 are mounted in anode 24 for monitoring the spatial distribution of a parameter associated with plasma 40. The embodiment of FIGS. 8-12 utilizes an array of 49 electrical sensors, as shown in FIG. 10. However, different numbers of sensors 210 may be utilized within the scope of the invention. Wires 212 connected to sensors 210 extend through feedthroughs 214 to a processing circuit 220 (FIG. 11) located external to plasma doping chamber 10. Wires 212 should have a plasma-resistant insulation, at least within plasma doping chamber 10. In one embodiment, wires 212 comprise coaxial cables that are terminated in 50 ohm resistors 222 (FIG. 11).

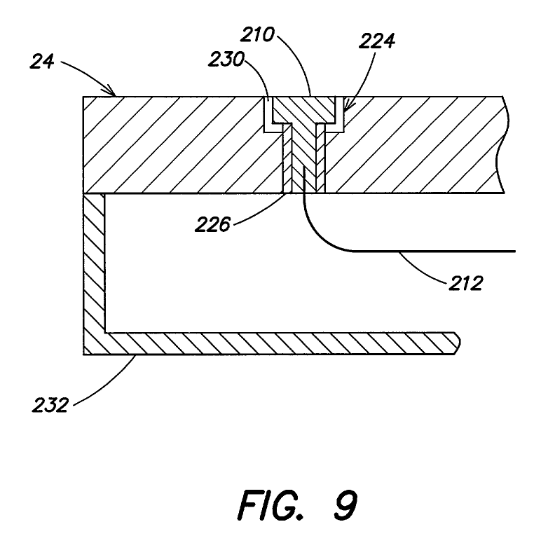

Referring to FIG. 9, each electrical sensor 210 may comprise a conductive element having a T-shaped cross-section. Each electrical sensor 210 is mounted within a recess 224 in anode 24 and is electrically isolated from anode 24 by an insulating sleeve 226. A gap 230 between electrical sensor 210 and anode 24 may be relatively small, typically on the order of about 0.1 millimeter, to limit disturbance to plasma 40. Arcing between electrical sensor 210 and anode 24 is not a concern, because these elements operate at nearly the same potential, typically ground. The voltage induced on electrical sensor 210 during sensing of charged particles is on the order of millivolts or less. The anode 24 may be provided with an electrically insulating cover 232 over its rear surface, opposite from plasma 40, to avoid plasma sensing at the rear surface and to provide protection for wires 212. As shown in FIG. 9, wires 212 may connect to the rear of electrical sensor 210 within cover 232.

An example of processing circuit 220 is shown in FIG. 11. Lead wires 212 from electrical sensors 210 are connected to respective amplifiers 240 to provide amplified sensor signals. The amplified sensor signals are supplied to an analog-to-digital converter 242 which converts the amplified sensor signals to digital values. The amplified sensor signals may be sampled simultaneously in response to a sample signal during operation of the pulsed plasma doping system. Analog-to-digital converter 242 may include a multi-channel converter or multiple individual converters. The output of analog-to-digital converter 242 is supplied through a data buffer 244 to a computer 250, such as a PC, for processing and storage of the digital values. The multiple electrical sensors 210 provide a map of the spatial distribution of plasma 40 within plasma doping chamber 10.

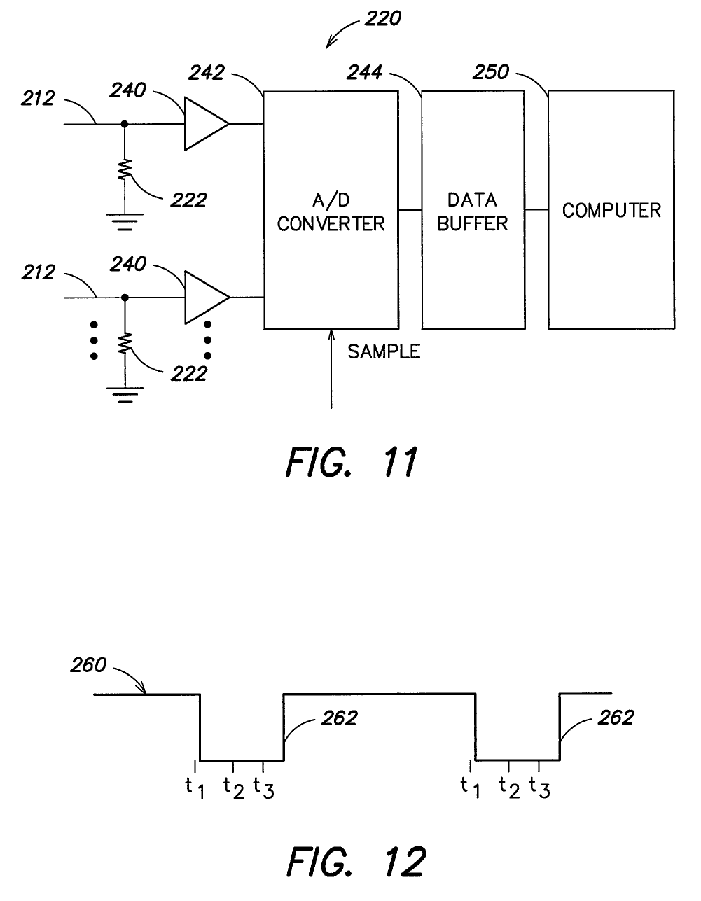

The sampling of a sensor signal is illustrated in FIG. 12. Sensor signal 260 represents the output of one of amplifiers 240 in processing circuit 220. Pulse source 30 (FIG. 1) is triggered at a plasma initiation time t₁, causing formation of plasma 40 and generation of sensor pulse 262 in response to the plasma. The analog-to-digital converter 242 may be activated to sample sensor pulse 262 from a sampling start time t₂ to a sampling end time t₃. As described below, the sampling start time t₂ and the sampling end time t₃ may vary, depending, for example, on the plasma parameter being monitored and the characteristics of the sensors. The sampling may be repeated each time the plasma doping system is triggered by pulse source 30 to provide real time monitoring of plasma 40. Each set of values acquired during simultaneous sampling of the sensor signals represents a map of the spatial distribution of plasma density within plasma doping chamber 10.

A variety of different sampling parameters may be utilized, depending on the plasma parameter being monitored. The sampling time may be defined as the time for which analog-to-digital converter 242 is enabled by the sample signal to make a measurement of the amplitude of the amplified sensor signals. Referring to FIG. 12, the sampling time is the period from sampling start time t₂ to sampling end time t₃. In general, the sampling time may be less than the width of the plasma doping pulse applied to platen 14 by pulse source 30 (FIG. 1) or may be greater than the width of the plasma doping pulse. In some cases, the sampling time may be much longer than the width of the plasma doping pulse. The sensor signal 260, as shown in FIG. 12, may have the same pulse width and duty cycle as the plasma doping pulses.

If the sampling time is long, the measurement samples many sensor pulses 262 and provides an output which is the average of the signal over the sampling time. This may be the case for optical sensors, where the sensor response time may be long compared to the plasma doping pulse width. However, in the case of electrical sensors, the sampling time can be very short, for example less than one microsecond. This allows measurement of the plasma parameter at different stages relative to the plasma doping pulse. A sample may be taken, for example, at or near the beginning of the plasma doping pulse when the plasma has just ignited, in a stable portion of the pulse when the plasma has reached a stable state, or in the afterglow period after the plasma doping pulse has ended. Although it is believed that sampling in the stable portion of the plasma doping pulse provides the best measure of uniformity, sampling at the beginning or in the afterglow period may provide satisfactory results and may be useful to assist in diagnostic purposes and to assist in making improvements to the plasma doping system. The simultaneous sampling described above refers to the fact that the sampling of all sensors may begin at the same time and may end at the same time. However, referring again to FIG. 12, the sampling start time t₂ and the sampling end time t₃ may have any desired timing relative to plasma initiation time t₁, and the sampling time may include one or more than one plasma doping pulse.

The sampling of electrical sensors 210 may involve simultaneous sampling of all electrical sensors 210 mounted on anode 24 or a subset of the electrical sensors 210. For example, the sensors 210 along a diameter of anode 24 may be sampled, or the sensors 210 around the periphery of anode 24 may be sampled.

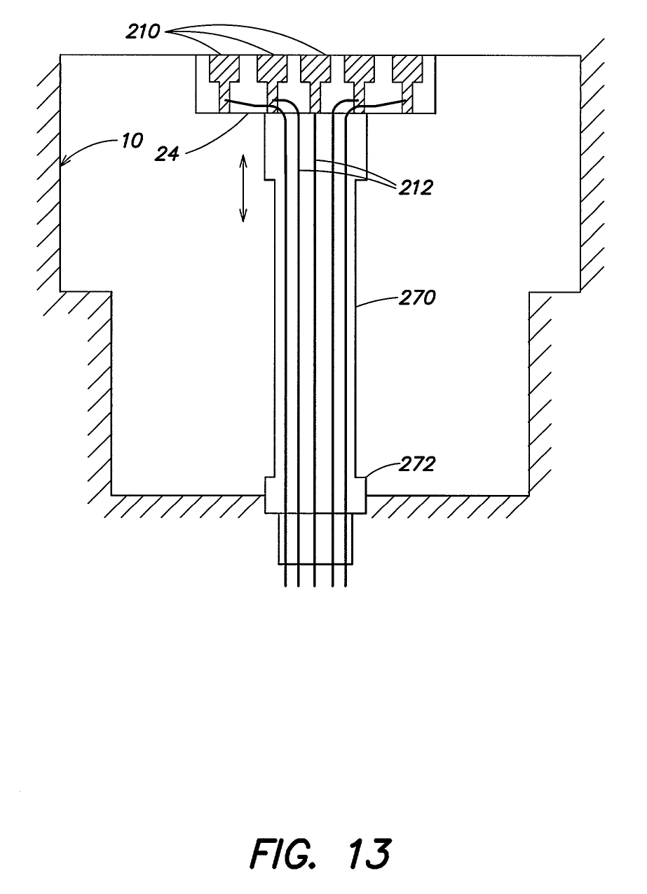

An eighth embodiment of the plasma monitor is described with reference to FIG. 13. As noted above in connection with FIG. 1, anode 24 may be movable toward or away from the wafer. In the embodiment of FIG. 13, anode 24 is coupled by a shaft 270 through a feedthrough 272 to an actuator (not shown) which moves anode 24 up or down in plasma doping chamber 10. In the embodiment of FIG. 13, wires 212 connected to electrical sensors 210 pass through a hollow portion of shaft 270 and feedthrough 272 to an externally-located processing circuit. This configuration avoids exposure of wires 212 to the plasma environment.

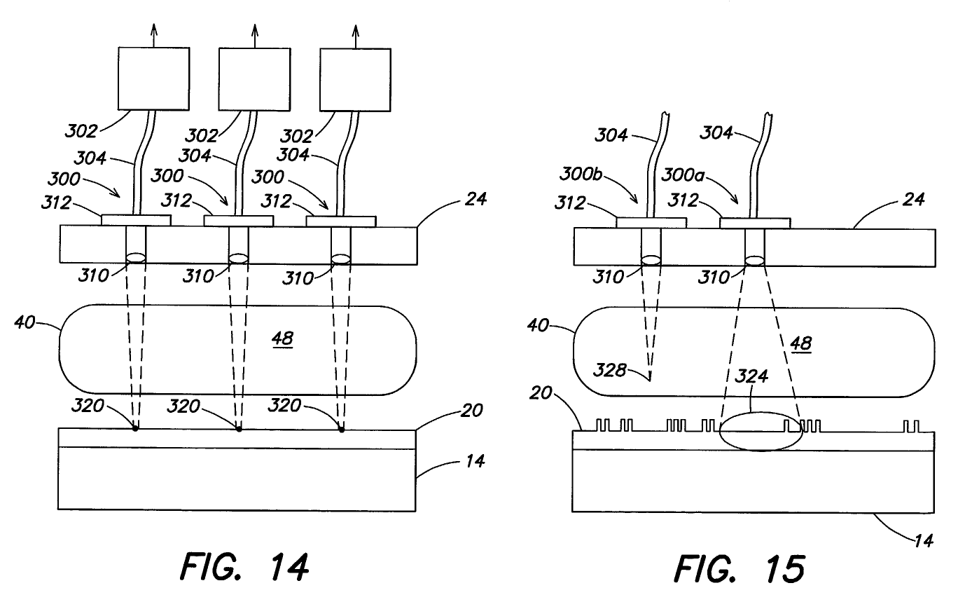

A ninth embodiment of the plasma monitor is described with reference to FIG. 14.

The embodiment of FIG. 14 utilizes optical sensors. Each optical sensor includes an optical probe 300 mounted in anode 24 for sensing optical emissions from plasma 48, a remotely-located photosensor 302 and an optical fiber 304 for carrying the sensed optical emissions to the remotely-located photosensor 302. Each optical probe 300 may include a lens 310 mounted in a lens support element 312. Each of the photosensors 302 generates an electrical signal in response to the sensed optical emissions. The electrical signals are provided to a processing circuit, which may be configured as described above in connection with FIGS. 11 and 12, for example. It will be understood that any desired number and configuration of optical sensors may be utilized.

In the embodiment of FIG. 14, each optical probe 300 is focused on a small area 320 on the surface of wafer 20. Each optical probe 300 senses optical emission from a limited sensing region of plasma 48. The limited sensing region may, for example, be conical, frustoconical or cylindrical in shape. Depending on the characteristics of the surface of wafer 20, optical probe 300 may also sense optical emissions from plasma 48 that are reflected by the wafer surface.

A tenth embodiment of the plasma monitor is described with reference to FIG. 15. The embodiment of FIG. 15 may utilize optical sensors as described above in connection with FIG. 14. In the embodiment of FIG. 15, optical probe 300a is focused on a relatively large area 324 of wafer 20. This configuration results in the averaging of reflections over different surface areas of the wafer. A second optical sensor 300b in the embodiment of FIG. 15 is focused at a region 328 within plasma 48. FIG. 15 shows different optical sensors focused at different regions for purposes of illustration. It will be understood that in a typical plasma doping system, all of the optical sensors may have the same or similar focusing characteristics. However, different optical sensors may have different focusing characteristics in the same plasma doping system if desired.

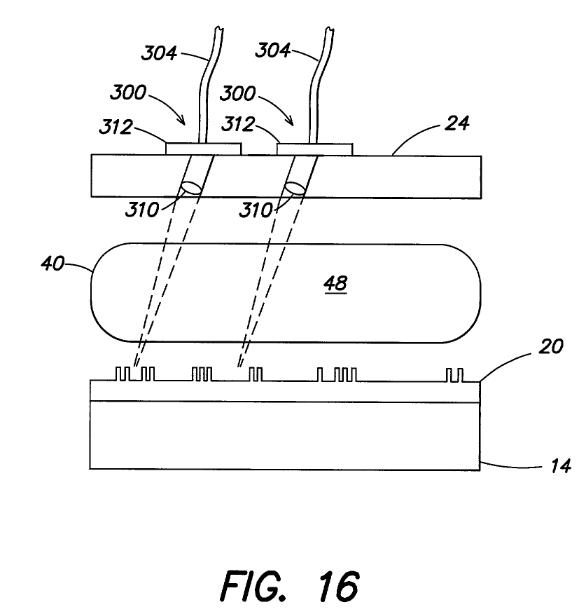

An eleventh embodiment of the plasma monitor is described with reference to FIG. 16. The embodiment of FIG. 16 may utilize optical sensors as described above in connection with FIG. 14. In the embodiment of FIG. 16, lens support elements 312 are configured to hold lenses 310 directed at an angle with respect to a normal to wafer 20. This configuration limits interference from reflections from the surface of wafer 20.

FIGS. 14-16 illustrate the principle that the optical probe 300 may be configured to sense optical emissions from a desired sensing region of plasma 48. For example, the optical characteristics and/or the orientation of lens 310 may be varied to achieve a desired sensing operation.

Measurements were taken with an optical sensor arrangement similar to the one shown in FIG. 14 and described above. The plasma was a pulsed BF₃ discharge. Four optical sensors with quartz focusing lens were positioned in anode 24 with radial positions of R=0, 3, 6 and 9 centimeters (cm) from the center. The wafer-to-anode distance was approximately 10 cm. All optical sensors were facing directly toward the silicon wafer surface with a focusing diameter of 5 millimeters. Optical signals were transferred to a spectrometer through a 4 channel optical vacuum feedthrough using 600 micrometer diameter optical fibers. The optical signals were integrated over a range of wavelengths between 350-400 nanometers.

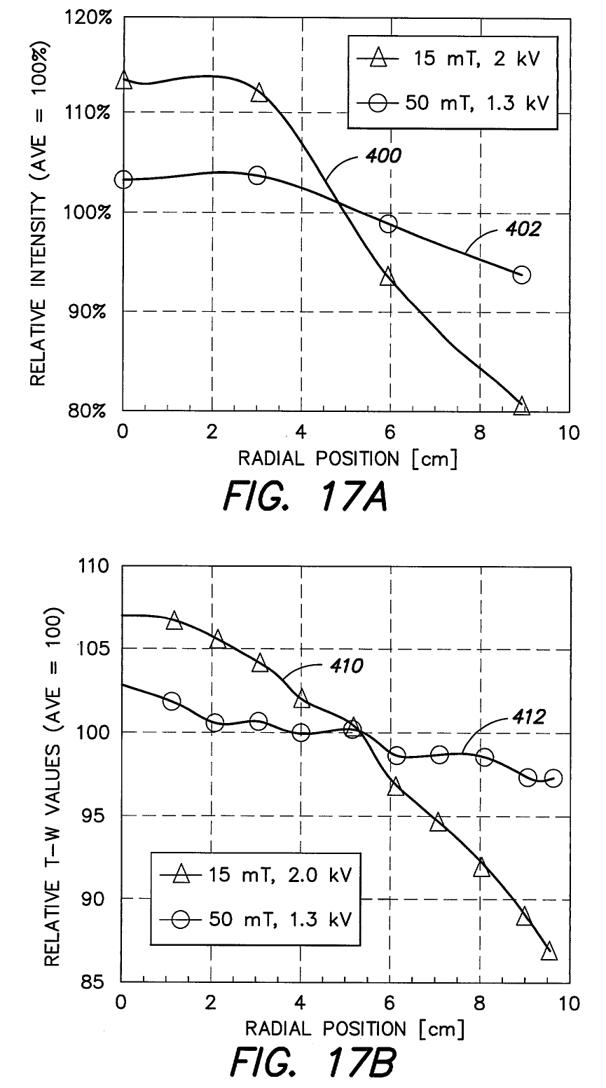

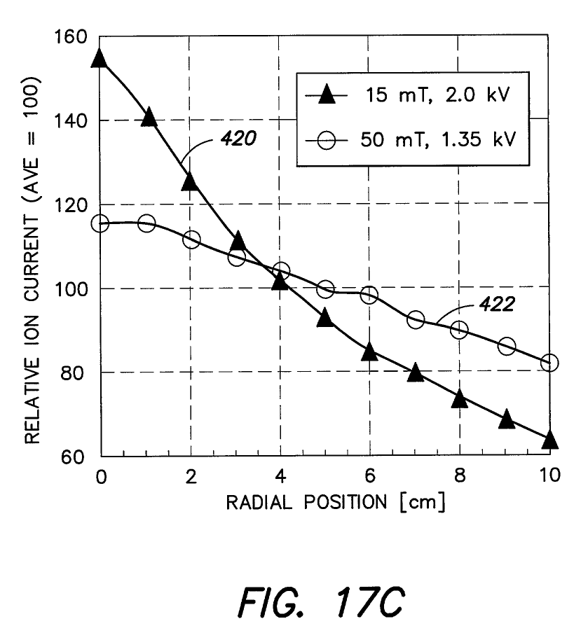

FIGS. 17A-17C are graphs of measured values as a function of radial position for three different measurement techniques. Each graph plots measurements taken under two plasma discharge conditions. The pressure is the BF₃ pressure in the discharge chamber, and the voltage is the pulse voltage applied to the hollow cathode 54 (FIG. 1). In each case, a pulse of about −200 volts was applied to the wafer 20.

In FIG. 17A, relative optical signal acquired with the optical sensors is plotted as a function of radial position for a chamber pressure of 15 millitorr and a hollow cathode pulse voltage of −2 kilovolts (curve 400) and for a chamber pressure of 50 millitorr and a hollow cathode pulse voltage of −1.3 kV (curve 402). FIG. 17B shows Therma-Wave data as a function of radial position under the same conditions as in FIG. 17A. Therma-Wave is a known technique for measuring wafer damage with a laser sensor. In FIG. 17B, curve 410 represents a chamber pressure of 15 millitorr and a hollow cathode pulse voltage of −2.0 kV, and curve 412 represents a chamber pressure of 50 millitorr and a hollow cathode pulse voltage of −1.3 kV. FIG. 17C shows relative ion current as a function of radial position under the same conditions as in FIG. 17A. The relative ion current was measured with a Langmuir probe. In FIG. 17C, curve 420 represents a chamber pressure of 15 millitorr and a hollow cathode pulse voltage of −2.0 kV, and curve 422 represents a chamber pressure of 50 millitorr and a hollow cathode pulse voltage of −1.35 kV. It may be observed that the optical signals of FIG. 17A exhibit similar radial profile shapes to the Therma-Wave values of FIG. 17B and the ion current values of FIG. 17C. For each measurement technique, the conditions of 15 millitorr and −2.0 kV produce a center peaked profile and for each measurement technique, the conditions of 50 millitorr and −1.3 kV produce a relatively uniform profile.

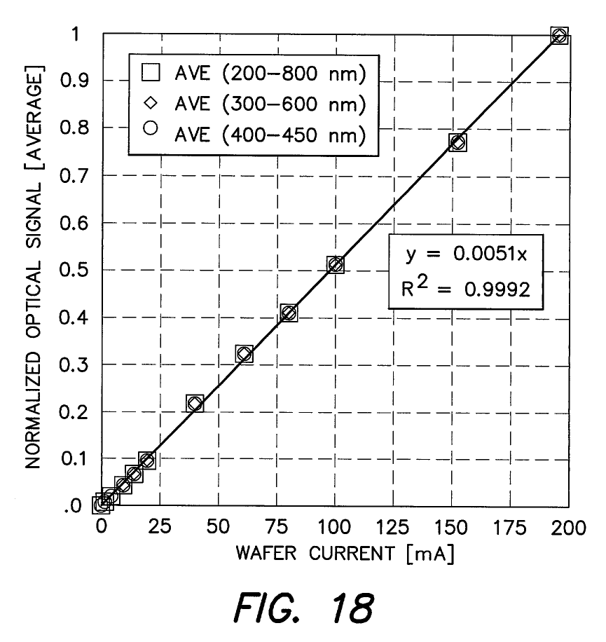

FIG. 18 is a graph of normalized optical signal as a function of wafer current in milliamps for different wavelength ranges. The optical signal was acquired by the optical sensor at the center location (R=0) and was provided to the spectrometer. BF₃ pressure was 30 millitorr and the plasma was generated by the wafer pulse. Measurements averaged over wavelength ranges of 200-800 nanometers, 300-600 nanometers and 400-450 nanometers showed nearly identical results. In each case the optical signal showed a very linear relationship with the wafer current.

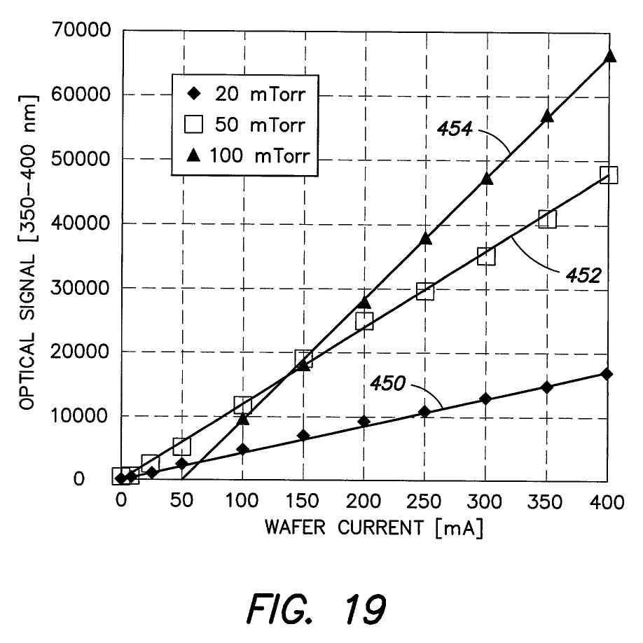

FIG. 19 is a graph of optical signal over a wavelength range of 350-400 nanometers as a function of wafer current in milliamps for different operating pressures. Curve 450 represents a pressure of 20 millitorr, curve 452 represents a pressure of 50 millitorr and curve 454 represents a pressure of 100 millitorr. The optical signal was acquired by the optical sensor at the center location (R=0) and was integrated between 350 and 400 nanometers.

It has been found that the optical sensor signal averaged or integrated over a selected range of wavelengths is representative of the plasma condition. The optical sensor signal may be averaged over the selected wavelength range or may be integrated to provide the area under the sensed plasma emission spectrum over the selected wavelength range. These functions may be performed, for example, by the computer 250 shown in FIG. 11. The optical sensor signal may be averaged or integrated over different wavelength ranges. Typically, the optical signal is averaged or integrated over a selected wavelength range having a width of 20 nanometers or greater. In some embodiments, wavelength ranges having widths of 50 to 600 nanometers may be utilized. The center of the selected wavelength range depends on the emission characteristics of the process gas. When the process gas is BF₃, the plasma emission is in the blue portion of the visible spectrum and the selected wavelength range may be centered at about 350-400 nanometers. The optical sensor may include an optical filter having a transmission characteristic that corresponds to the selected wavelength range.

The plasma monitor has been described above in connection with dose uniformity monitoring. The optical sensor can also be used as a plasma repeatability sensor. The optical sensor has sufficient sensitivity to detect approximately 1% or less changes in the plasma condition. As shown in FIGS. 18 and 19, a linear relation exists between the optical signal and the wafer current, which is representative of plasma density. An optical sensor focused on the plasma can detect a plasma condition change which may produce day-to-day or batch-to-batch process variations. Typically, the optical sensor is characterized by a tradeoff between optical sensitivity and optical resolution.

The plasma monitor can be utilized in a feedback control system to control the plasma doping process. For example, the sensed plasma parameter can be used to adjust plasma doping conditions, such as plasma doping time, chamber pressure, plasma ignition voltage and the like.

It should be understood that various changes and modifications of the embodiments shown in the drawings described in the specification may be made within the spirit and scope of the present invention. Accordingly, it is intended that all matter contained in the above description and shown in the accompanying drawings be interpreted in an illustrative and not in a limiting sense. The invention is limited only as defined in the following claims and the equivalents thereto.

What is claimed is:

1. Plasma doping apparatus comprising:
a plasma doping chamber;
a platen located in said plasma doping chamber for supporting a workpiece;
an anode spaced from said platen in said plasma doping chamber;
a process gas source coupled to said plasma doping chamber, wherein a plasma containing ions of the process gas is produced in a plasma discharge region between said anode and said platen;
a pulse source for applying pulses between said platen and said anode for accelerating ions from the plasma into the workpiece; and
a plasma monitor comprising a sensing device for sensing a spatial distribution of a parameter of the plasma.

2. Plasma doping apparatus as defined in claim 1, wherein said sensing device comprises a linear array of sensors disposed within said plasma doping chamber in spaced relation to the workpiece.

3. Plasma doping apparatus as defined in claim 1, wherein said sensing device comprises a circular array of sensors disposed within said plasma doping chamber in spaced relation to the workpiece.

4. Plasma doping apparatus as defined in claim 1, wherein said sensing device comprises a two-dimensional array of sensors disposed within said plasma doping chamber in spaced relation to the workpiece.

5. Plasma doping apparatus as defined in claim 1, wherein said sensing device comprises a radial array of sensors disposed within said plasma doping chamber in spaced relation to the workpiece.

6. Plasma doping apparatus as defined in claim 1, wherein said sensing device comprises one or more optical sensors.

7. Plasma doping apparatus as defined in claim 6, wherein said one or more optical sensors are configured for broadband optical sensing.

8. Plasma doping apparatus as defined in claim 6, wherein said one or more optical sensors are configured for narrow band optical sensing.

9. Plasma doping apparatus as defined in claim 1, wherein said sensing device comprises one or more electrical sensors.

10. Plasma doping apparatus as defined in claim 1, wherein said sensing device comprises one or more sensors mounted in or near said anode.

11. Plasma doping apparatus as defined in claim 1, wherein said sensing device comprises an image sensor disposed in said plasma doping chamber in spaced relation to the workpiece.

12. Plasma doping apparatus as defined in claim 1, wherein said sensing device comprises a movable sensor disposed in said plasma doping chamber in spaced relation to the workpiece, and an actuator for moving the sensor with respect to the plasma.

13. Plasma doping apparatus as defined in claim 1, wherein said sensing device is configured for sensing the spatial distribution of the plasma density in the plasma discharge region.

14. Plasma doping apparatus as defined claim 1, wherein said sensing device is configured for sensing a plasma parameter that is indicative of dose distribution of ions implanted into the workpiece.

15. Plasma doping apparatus as defined in claim 1, further comprising a dose processor for processing measurements by the sensing device and estimating a dose distribution of ions implanted into the workpiece.

16. Plasma doping apparatus as defined in claim 15, further comprising a Faraday cup for sensing ion current, wherein the dose processor is responsive to measurements by the beam sensor for estimating ion dose delivered to the workpiece.

17. Plasma doping apparatus as defined in claim 1, wherein said sensing device is configured for sensing the spatial distribution of plasma density during plasma doping of the workpiece.

18. Plasma doping apparatus as defined in claim 1, wherein said sensing device comprises an array of sensors mounted in said anode, said plasma monitor further comprising processing circuitry connected to the sensors.

19. Plasma doping apparatus as defined in claim 18, wherein said array of sensors comprises electrical sensors mounted in said anode and electrically isolated from said anode.

20. Plasma doping apparatus as defined in claim 19, further comprising an electrically insulating cover over a rear surface of said anode.

21. Plasma doping apparatus as defined in claim 18, wherein said processing circuitry includes circuitry for simultaneous sampling of all or a selected group of said sensors.

22. Plasma doping apparatus as defined in claim 18, wherein said processing circuitry includes circuitry for sampling all or a selected group of said sensors during a stable portion of the pulses applied between said platen and said anode.

23. Plasma doping apparatus as defined in claim 18, wherein said processing circuitry includes circuitry for sampling all or a selected group of said sensors at or near the beginning of each of the pulses applied between said platen and said anode.

24. Plasma doping apparatus as defined in claim 18, wherein said processing circuitry includes circuitry for sampling all or a selected group of said sensors during an afterglow period following each of the pulses applied between said platen and said anode.

25. Plasma doping apparatus as defined in claim 18, wherein said processing circuitry includes circuitry for sampling all or a selected group of said sensors during a sampling time that is less than the width of each of the pulses applied between said platen and said anode.

26. Plasma doping apparatus as defined in claim 18, wherein said processing circuitry includes circuitry for sampling all or a selected group of said sensors during a sampling time that is greater than the width of each of the pulses applied between said platen and said anode.

27. Plasma doping apparatus as defined in claim 18, wherein said processing circuitry includes circuitry for sampling all or a selected group of said sensors during a sampling time that includes two or more of the pulses applied between said platen and said anode.

28. Plasma doping apparatus comprising:
a plasma doping chamber;
a platen located in said plasma doping chamber for supporting a workpiece;
an anode spaced from said platen in said plasma doping chamber;
a process gas source coupled to said plasma doping chamber, wherein a plasma containing ions of the process gas is produced in a plasma discharge region between said anode and said platen;
a pulse source for applying pulses between said platen and said anode for accelerating ions from the plasma into the workpiece; and
a plasma monitor comprising one or more optical sensors mounted on or near said anode for sensing a spatial distribution of the plasma, wherein the spatial distribution of the plasma is indicative of dose distribution of ions implanted into the workpiece.

29. Plasma doping apparatus as defined in claim 28, wherein said one or more optical sensors comprise a linear array of sensors disposed within said plasma doping chamber in spaced relation to the workpiece.

30. Plasma doping apparatus as defined in claim 28, wherein said one or more optical sensors comprise a two-dimensional array of sensors disposed within said plasma doping chamber in spaced relation to the workpiece.

31. Plasma doping apparatus as defined in claim 28, wherein said one or more optical sensors comprise an image sensor disposed in said plasma doping chamber in spaced relation to the workpiece.

32. Plasma doping apparatus as defined in claim 28, wherein said one or more optical sensors comprise a movable sensor disposed in said plasma doping chamber in spaced relation to the workpiece, and an actuator for moving the sensor with respect to the plasma.

33. Plasma doping apparatus as defined in claim 28, wherein said one or more optical sensors each comprise an optical probe mounted in said plasma doping chamber, a remotely-located photosensor and an optical fiber for carrying the sensed optical emission to the remotely-located photosensor.

34. Plasma doping apparatus as defined in claim 28, wherein said one or more optical sensors are configured for sensing a spatial distribution of the plasma over a selected wavelength range having a width of about 20 nanometers or greater.

35. Plasma doping apparatus as defined in claim 34, wherein the selected wavelength range has a width of about 50-600 nanometers.

36. Plasma doping apparatus as defined in claim 34, wherein the selected wavelength range matches optical emissions from the process gas.

37. Plasma doping apparatus as defined in claim 34, wherein the process gas is BF₃ and the selected wavelength range is centered at about 350-400 nanometers.

38. Plasma doping apparatus as defined in claim 34, wherein said plasma monitor further comprises processing circuitry for averaging sensed optical emissions over the selected wavelength range.

39. Plasma doping apparatus as defined in claim 34, wherein said plasma monitor further comprises processing circuitry for integrating sensed optical emissions over the selected wavelength range.

40. A method for plasma doping, comprising:
supporting a workpiece on a platen in a plasma doping chamber;
generating a plasma and accelerating ions from the plasma into the workpiece; and
sensing a spatial distribution of a plasma parameter.

41. A method as defined in claim 40, wherein the step of sensing a spatial distribution of a plasma parameter comprises optically sensing the spatial distribution of the plasma parameter with an array of optical sensors.

42. A method as defined in claim 40, wherein the step of sensing a spatial distribution of a plasma parameter comprises sensing the spatial distribution of the plasma parameter with an image sensor disposed in the plasma doping chamber.

43. A method as defined in claim 40, wherein in the step of sensing a spatial distribution of plasma parameter comprises moving a sensor disposed in said plasma doping chamber with respect to the plasma.

44. A method as defined claim 40, wherein the step of sensing a spatial distribution of a plasma parameter comprises sensing the spatial distribution of a plasma parameter that is indicative of dose distribution of ions implanted into the workpiece.

45. A method as defined in claim 40, wherein the step of sensing a spatial distribution of a plasma parameter comprises electrically sensing the spatial distribution of the plasma parameter with an array of electrical sensors.

46. A method as defined in claim 40, wherein the step of sensing a spatial distribution of a plasma parameter comprises sensing the spatial distribution of the plasma parameter with an array of sensors and simultaneously sampling all or a selected group of the sensors during the step of generating a plasma and accelerating ions from the plasma into the workpiece.

47. A method as defined in claim 40, wherein the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of the one or more sensors during stable portions of the plasma doping pulses.

48. A method as defined in claim 40, wherein in the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of the one or more sensors at or near a beginning of each of the plasma doping pulses.

49. A method as defined in claim 40, wherein in the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of the one or more sensors during an afterglow period following each of the plasma doping pulses.

50. A method as defined in claim 40, wherein in the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of one or more sensors during a sampling time that is less than the width of each of the plasma doping pulses.

51. A method as defined in claim 40, wherein in the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of the one or more sensors during a sampling time that is greater than the width of each of the plasma doping pulses.

52. A method as defined in claim 40, wherein in the step of generating a plasma and accelerating ions comprises generating a pulsed plasma in response to plasma doping pulses and wherein the step of sensing a spatial distribution of a plasma parameter comprises sensing the plasma parameter with one or more sensors and sampling outputs of the one or more sensors during a sampling time that includes two or more of the plasma doping pulses.

53. A method for plasma doping, comprising:
supporting a workpiece on a platen in a plasma doping chamber;
generating a plasma and accelerating ions from the plasma into the workpiece; and
optically sensing a spatial distribution of the plasma, wherein the spatial distribution of the plasma is indicative of dose distribution of ions implanted into the workpiece.

54. A method as defined in claim 53, wherein in the step of optically sensing, a spatial distribution of the plasma comprises optically sensing the plasma with an array of optical sensors.

55. A method as defined in claim 54, further comprising the steps of processing the sensed spatial distribution of the plasma and estimating a dose distribution of ions implanted into the workpiece.

56. A method as defined in claim 53, wherein the step of supporting a workpiece on a platen comprises supporting a semiconductor wafer on a platen.

57. A method as defined in claim 53, wherein the step of optically sensing a spatial distribution of the plasma comprises sensing optical emissions from the plasma over a selected wavelength range having a width of about 20 nanometers or greater.

58. A method as defined in claim 57, wherein the step of sensing optical emissions from the plasma over a selected wavelength range comprises sensing optical emissions over a selected wavelength range having a width of about 50-600 nanometers.

59. A method as defined in claim 57, comprising matching the selected wavelength range to optical emissions from a process gas used to generate the plasma.

60. A method as defined in claim 57, wherein the plasma is generated from BF₃ and the selected wavelength range is centered at about 350-400 nanometers.

61. A method as defined in claim 57, further comprising averaging sensed optical emissions over the selected wavelength range.

62. A method as defined in claim 57, further comprising integrating sensed optical emissions over the selected wavelength range.

63. A method for plasma doping, comprising:
supporting a workpiece on a platen in a plasma doping chamber;
generating a plasma and accelerating ions from the plasma into the workpiece; and
electrically sensing a spatial distribution of the plasma, wherein the spatial distribution of the plasma is indicative of dose distribution of ions implanted into the workpiece.

64. A method as defined in claim 63, wherein the step of electrically sensing a spatial distribution of the plasma comprises electrically sensing the plasma with an array of electrical sensors.

65. Plasma doping apparatus comprising:
a plasma doping chamber;
a platen located in said plasma doping chamber for supporting a workpiece;
an anode spaced from said platen in said plasma doping chamber;
a process gas source coupled to said plasma doping chamber, wherein a plasma containing ions of the process gas is produced in a plasma discharge region between said anode and said platen;
a pulse source for applying pulses between said platen and said anode for accelerating ions from the plasma into the workpiece; and
a plasma monitor comprising an optical sensor for sensing optical emissions from the plasma over a selected wavelength range and processing circuitry connected to the optical sensor for processing the sensed optical emissions over the selected wavelength range.

66. Plasma doping apparatus as defined in claim 65, wherein the selected wavelength range has a width of about 20 nanometers or greater.

67. Plasma doping apparatus as defined in claim 65, wherein the selected wavelength range has a width of about 50-600 nanometers.

68. Plasma doping apparatus as defined in claim 65, wherein the selected wavelength range matches optical emissions from the process gas.

69. Plasma doping apparatus as defined in claim 65, wherein the process gas comprises BF₃ and the selected wavelength range is centered at about 350-400 nanometers.

70. Plasma doping apparatus as defined in claim 65, wherein the processing circuitry averages the sensed optical emissions over the selected wavelength range.

71. Plasma doping apparatus as defined in claim 65, wherein the processing circuitry integrates the sensed optical emissions over the selected wavelength range.

72. A method for plasma doping, comprising:
supporting a workpiece on a platen in a plasma doping chamber;
generating a plasma and accelerating ions from the plasma into the workpiece;
sensing optical emissions from the plasma over a selected range of wavelengths; and
processing sensed optical emissions over the selected wavelength range to provide a measurement value that is representative of a condition of the plasma.

73. A method as defined in claim 72, wherein the step of processing the sensed optical emissions comprises averaging the sensed optical emissions over the selected wavelength range.

74. A method as defined in claim 72, wherein the step of processing the sensed optical emissions comprises integrating the sensed optical emissions over the selected wavelength range.
